(19) United States
(12) Patent Application Publication
(10) Pub. No.: US 2016/0018710 A1
(43) Pub. Date: Jan. 21, 2016

(54) DISPLAY PANEL, ARRAY SUBSTRATE AND METHOD FOR MANUFACTURING THE SAME

(71) Applicant: Li CHAI, Shenzhen (CN)

(72) Inventor: Li CHAI, Shenzhen (CN)

(21) Appl. No.: 14/416,382

(22) PCT Filed: Aug. 22, 2014
(86) PCT No.: PCT/CN2014/085057

§ 371 Date: Aug. 20, 2015

(30) Foreign Application Priority Data
Jul. 21, 2014 (CN) 201410348365.3

(51) Int. Cl. G02F 1/1362; H01L 23/532; H01L 23/522; G02F 1/1368; H01L 27/12

(52) U.S. Cl. CPC G02F 1/136286; G02F 1/1368; G02F 1/136227; H01L 27/124; H01L 27/1259; H01L 23/5226; H01L 23/53209; G02F 2001/136295

(57) ABSTRACT

A display panel, an array substrate, and a method for manufacturing the same are provided. The array substrate comprises a plurality of pixel units each having a gate line and a common line. The gate line comprises a first line segment and a second line segment. An electric connection structure is disposed in the interrupted region between the first line segment and the second line segment, so that the first line segment and the second line segment are electrically connected with each other through the electric connection structure, and the common line extends through said interrupted region in a direction perpendicular to the gate line, and is in insulated contact with the first line segment and the second line segment. The present disclosure can improve the uniformity of the optimum common voltage, thereby improving the product quality.

The present application claims benefit of Chinese patent application CN 201410348365.3, entitled “Display Panel, Array Substrate and Method for Manufacturing the Same” and filed on Jul. 21, 2014, which is incorporated herein by reference.

### TECHNICAL FIELD

The present disclosure relates to the technical field of liquid crystal display. Specifically, the present disclosure relates to a display panel, an array substrate, and a method for manufacturing the array substrate.

### TECHNICAL BACKGROUND

As the information society develops, people's demand for display device grows. As a result, the industry of liquid crystal display panel is booming rapidly. With the increase of the production of liquid crystal display panel, people's demand for the quality and yield rate of the product also becomes higher. Therefore, it is a major issue in the art to improve the product quality, reduce the reject ratio, and save cost.

At present, in designing an array substrate, a common line is usually formed in the same layer as a gate line, and is parallel thereto, and all the common lines are short-circuited together outside an effective display area. During operation of the display panel, a peripheral circuit provides a common voltage through one end or both ends of a common line.

It is found that there are the following defects in the prior art. In the above-mentioned design, as the dimension of a TFT-LCD grows, the common line is required to be longer and longer. In this case, the voltage drop on the common line renders the optimum common voltages at different positions along the common line to be different. For example, the common voltage at an end of the common line can be larger than that at the center thereof, rendering poor voltage uniformity along the common line. Consequently, image sticking can easily occur.

Therefore, a technical solution for effectively improving the uniformity of the optimum common voltage and thereby improving product quality is needed.

### SUMMARY OF THE INVENTION

One of the technical problems to be solved by the present disclosure is to provide an array substrate, with which the uniformity of the optimum common voltage can be improved, and thereby product quality can be increased. In addition, a method for manufacturing the array substrate and a display panel comprising said array substrate are further provided.

(1) In order to solve the above-mentioned technical problem, the present disclosure provides an array substrate comprising a plurality of pixel units each having a gate line and a common line, wherein

the gate line comprises a first line segment and a second line segment configured to be interrupted from each other,

an electric connection structure is disposed at an interrupted region between the first line segment and the second line segment, so that the first line segment and the second line segment are electrically connected with each other through the electric connection structure, and

the common line extends through said interrupted region in a direction perpendicular to the gate line, and is in insulated contact with the first line segment and the second line segment.

(2) In a preferred embodiment of (1), the electric connection structure comprises via holes and an electric connecting line.

(3) In a preferred embodiment of (1) or (2), the via holes respectively correspond to ends of the first line segment and the second line segment that are adjacent to each other,

the electric connecting line electrically connects the first line segment with the second line segment through the via holes, and

wherein the electric connecting line is made of any one selected from a group consisting of Ta, Mo, Cr, Ti/Al/Ti, Al/Mo, Mo/Ta, and Mo/W.

(4) On another aspect, the present disclosure further provides a display panel comprising an array substrate, wherein the array substrate comprises a plurality of pixel units each having a gate line and a common line,

wherein the gate line comprises a first line segment and a second line segment configured to be interrupted from each other,

an electric connection structure is disposed at an interrupted region between the first line segment and the second line segment, so that the first line segment and the second line segment are electrically connected with each other through the electric connection structure, and

the common line extends through said interrupted region in a direction perpendicular to the gate line, and is in insulated contact with the first line segment and the second line segment.

In a preferred embodiment of (4), the electric connection structure comprises via holes and an electric connecting line.

In a preferred embodiment of (4) or (5), the via holes respectively correspond to ends of the first line segment and the second line segment that are adjacent to each other,

the electric connecting line electrically connects the first line segment with the second line segment through the via holes, and

wherein the electric connecting line is made of any one selected from a group consisting of Ta, Mo, Cr, Ti/Al/Ti, Al/Mo, Mo/Ta, and Mo/W.

(7) On another aspect, the present disclosure further provides a method for manufacturing an array substrate, comprising the following steps:

forming a gate, a gate line, and a common line on a substrate, wherein the gate line comprises a first line segment and a second line segment configured to be interrupted from each other, and the common line extends through an interrupted region in a direction perpendicular to the gate line, and is in insulated contact with the first line segment and the second line segment,

forming a first insulation layer on the gate, gate line and the common line, and forming in the first insulation layer via holes, which respectively correspond to the ends of the first line segment and the second line segment that are adjacent to each other,

forming a data line, a source, a drain, and an electric connecting line on the first insulation layer, the electric connecting line electrically connecting the first line segment with the second line segment through the via holes formed in the first insulation layer, and

forming a second insulation layer on the data line, source, drain, and the electric connecting line, forming a via hole in the second layer and a pixel electrode on the second insulation layer, the drain being electrically connected with the pixel electrode through the via hole formed in the second insulation layer.

(8) In a preferred embodiment of (7), the electric connecting line is made of any one selected from a group consisting of Ta, Mo, Cr, Ti/Al/Ti, Al/Mo, Mo/Ta, and Mo/W.

As compared with the prior art, one or more embodiment of the above technical solutions has the following beneficial effects.

According to the present disclosure, each of the gate lines of the array substrate is configured to be interrupted therein, so that the common lines each can pass through the interrupted region formed by the gate line and be short-circuited with one another in the effective display area, and at the same time the interrupted gate line segments are electrically connected with each other by providing an electric connecting line. In this manner, the conductivity of the gate line would not be affected, and the uniformity of the optimum common voltage can be improved by short-circuiting the common lines together, thereby improving the product quality.

Other features and advantages of the present disclosure will be further explained in the following description, and are partially become more readily evident therefrom, or be understood through implementing the present disclosure. The objectives and advantages of the present disclosure will be achieved through the structure specifically pointed out in the description, claims, and the accompanying drawings.

### BRIEF DESCRIPTION OF THE ACCOMPANYING DRAWINGS

The accompanying drawings, which form a part of the description, are used to further illustrate the present disclosure in conjunction with the embodiments. It should be understood that the accompanying drawings should not be construed as limitations to the present disclosure. In the drawings:

FIG. 1 schematically shows the structure of a pixel unit in the prior art,

FIG. 2 schematically shows an equivalent circuit of the pixel unit as shown in FIG. 1,

FIG. 3 schematically shows the structure of a display panel according to an example of the present disclosure,

FIG. 4 schematically shows the structure of a pixel unit according to an example of the present disclosure,

FIG. 5 shows a sectional view of line AA′ as shown in FIG. 4,

FIG. 6 schematically shows a patterning of a first layer and that of a second layer during the manufacturing of an array substrate,

FIG. 7 schematically shows an equivalent circuit of the pixel unit as shown in FIG. 4, and

FIG. 8 shows a flow chart of a method for manufacturing the array substrate according to an example of the present disclosure.

### DETAILED DESCRIPTION OF THE EMBODIMENTS

The present disclosure will be explained in detail with reference to the embodiments and the accompanying drawings, whereby it can be fully understood about how to solve the technical problem by the technical means according to the present disclosure and achieve the technical effects thereof, and thus the technical solution according to the present disclosure can be implemented. It is important to note that as long as there is no structural conflict, various embodiments as well as the respective technical features mentioned herein may be combined with one another in any manner, and the technical solutions obtained all fall within the scope of the present disclosure.

The following specific examples, by means of which the present disclosure can be implemented, are explained with reference to the accompanying drawings. The directional terms in the present disclosure, such as up, down, left, and right, etc., merely indicate the directions as shown in the accompanying drawings. Therefore, the directional terms are used to explain and understand the present disclosure, instead of limiting the present disclosure.

In addition, in order to be clear, the size and thickness of each component as shown in the accompanying drawings are demonstrated randomly. The present disclosure is not limited thereto.

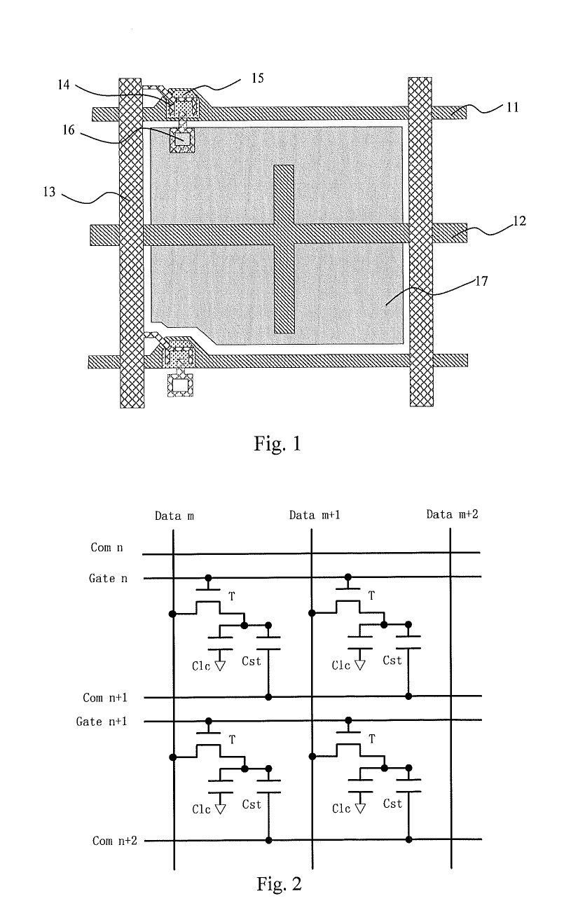

FIG. 1 schematically shows the structure of a pixel unit in the prior art. As shown in FIG. 1, the pixel unit comprises a gate line 11, a common line 12, a data line 13, a switching element 14, a Si island 15, a via hole 16, and a pixel electrode 17. The drain of the switching element 14 is electrically connected with the pixel electrode 17 through the via hole 16.

FIG. 2 shows an equivalent circuit of the pixel unit of FIG. 1. As shown in FIG. 2, the gate of a switching element T of each pixel unit is connected to the gate line (for example, Gate n or Gate n+1) of the pixel unit, and the source of the switching element T is connected to the data line (such as Data m or Data m+1) thereof. In addition, each pixel unit further comprises a liquid crystal capacitor Clc and a storage capacitor Cst. One end of each storage capacitor Cst is connected to the drain of the switching element T, and the other end thereof is connected to the common line (such as Com n or Com n+1).

As shown in FIG. 2, the common lines are independent and separated from each other in the effective display area. It is easy to understand that with such a structure, the voltage drop on the common line can cause the optimum common voltages at different positions along the common line to be inconsistent, rendering poor uniformity of common voltage. Consequently, image sticking can easily occur.

The examples according to the present disclosure provide technical solutions for solving the above technical problem. The examples will be explained with reference to the accompanying drawings.

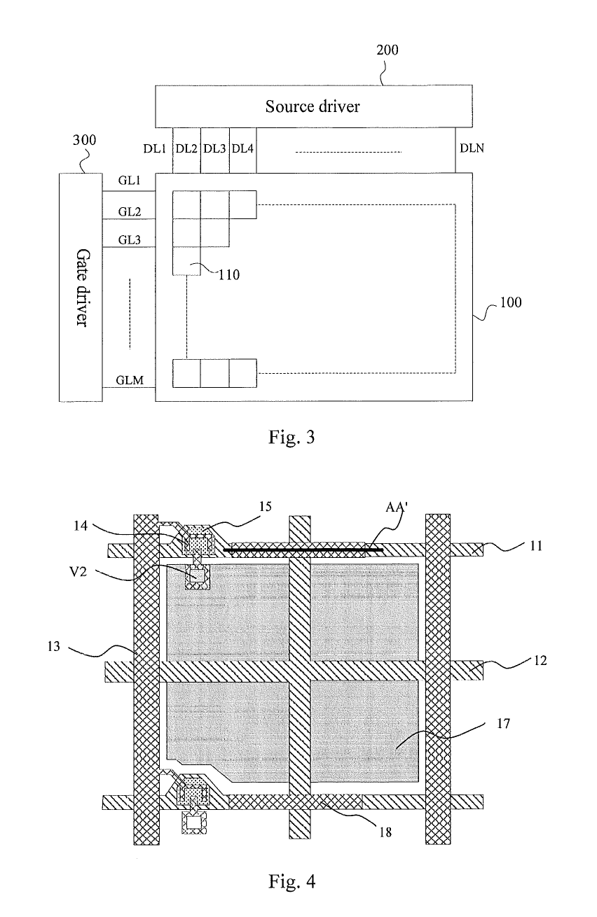

Reference can be made to FIG. 3, which shows the structure of a display panel according to an example of the present disclosure. The display panel comprises an image display area 100, a source driver 200, and a gate driver 300. The image display area 100 comprises an array formed by a plurality of data lines (such as the N data lines DL1-DLN as shown in the drawings) and a plurality of scan lines (such as the M scan lines GL1-GLM as shown in the drawings) that are arranged perpendicular to the plurality of data lines, as well as a plurality of pixels 110. The source driver 200 transmits a data signal provided by the plurality of data lines coupled therewith to the image display area 100. The gate driver 300 transmits a scan signal provided by the plurality of scan lines coupled therewith to the image display area 100.

It should be noted that the pixel according to the present disclosure comprises a plurality of pixel units respectively disposed in a plurality pixel regions formed by the plurality of data lines and the plurality of scan lines that are arranged perpendicular to the plurality of data lines. In this example, a pixel unit can be of different colors, such as a red (R) one, a green (G) one, or a blue (B) one, etc.

Reference can be made to FIG. 4, which shows the structure of a pixel unit according to an example of the present disclosure. The pixel unit can be used in the display panel of FIG. 3.

As shown in FIG. 4, the pixel unit comprises a gate line 11, a common line 12, a switching element 14, a Si island 15, a via hole V2 (hereinafter referred to as the second via hole), a pixel electrode 17, and an electric connecting line 18. The pixel electrode 17 is electrically connected to the switching element 14 through the second via hole V2. The gate line 11 controls the on-off state of the switching element 14. The pixel electrode 17 is preferably a transparent pixel electrode made of ITO material.

It should be noted that according to an example of the present disclosure, each of the gate lines is configured to be interrupted therein, so that the common lines each can pass through the interrupted region of the gate line and be short-circuited with one another within the effective display area. In the meantime, the interrupted gate line segments (hereinafter referred to as the first line segment and the second line segment) are electrically connected with each other by providing an electric connection structure arranged at the interrupted region. In this manner, the conductivity of the gate line would not be affected, and also the uniformity of the optimum common voltage can be improved by short-circuiting the common lines together.

It should be noted that in the present disclosure, the structure of the pixel unit is not limited to that as shown in FIG. 4. Other arrangements or structures, which can improve the uniformity of the optimum common voltage based on the principle of the present disclosure, can all be applied in the present disclosure, such as a pixel unit comprising a main pixel region and a sub pixel region. Although the structure of the pixel unit as shown in FIG. 4 is used to explain the present disclosure in detail, the present disclosure is not limited thereto.

In order to better explain the present example, the gate line and the common line of the pixel unit will be illustrated in detail with reference to FIG. 6.

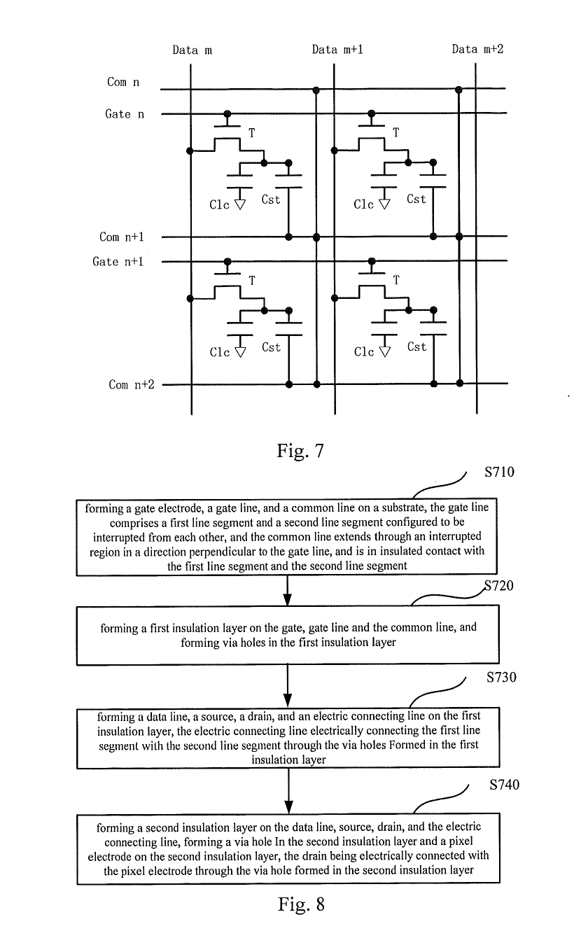

FIG. 6 schematically shows a patterning of a first layer and that of a second layer of a pixel unit during the manufacturing of an array substrate. As shown in FIG. 6, when forming the patterning of the first layer, the gate line 11, a gate G, and the common line 12 are formed. The gate line 11 is configured to comprise a first line segment 11a and a second line segment 11b interrupted from each other. The common line 12 passes through the interrupted region in a direction perpendicular to the gate line 11, and is in insulated contact with the first line segment 11a and the second line segment 11b. As shown in FIG. 7, each pair of adjacent common lines are short-circuited with each other, and all the common lines together form a pattern of a mesh. When forming the patterning of the second layer, a first insulation layer (not shown) is formed on the gate line 11 and the common line 12, a Si island 15 is formed on the gate G, and first via holes V1 are formed in the first insulation layer. The first via holes V1 correspond to the respective ends of the first line segment 11a and the second line segment 11b that are adjacent to each other. Further, in a subsequent manufacturing step, the first line segment 11a and the second line segment 11b are electrically connected with each other through an electric connection structure comprising the first via holes V1 and a metallic layer.

FIG. 7 shows an equivalent circuit of the pixel unit of FIG. 4. As shown in FIG. 7, each pixel unit comprises a switching element T, a storage capacitor Cst, and a liquid crystal capacitor Clc1. The switching element T is preferably a thin film transistor. The gate of the switching element T is connected to the gate line (such as Gate n or Gate n+1) of the pixel unit, and the source of the switching element T is connected to the data line (such as Data m or Data m+1) thereof. One end of the storage capacitor Cst is connected to the drain of the switching element T, and the other end thereof is connected to the common line (such as Com n or Com n+1).

It should be noted that the common lines are short-circuited with one another, and all common lines together form a pattern of a mesh. In this case, as compared with the common lines arranged independent from each other in the prior art, those according to the present disclosure can effectively reduce the influence caused by the voltage drop thereon, thereby improving the uniformity of the optimum common voltage.

FIG. 8 shows a flow chart of a method for manufacturing the array substrate according to an example of the present disclosure. The steps of the method will be explained in detail with reference to FIG. 8.

In step 710, gates, gate lines, and common lines are formed on a substrate. A gate line comprises a first line segment and a second line segment configured to be interrupted from each other. A common line extends through said interrupted region in a direction perpendicular to the gate line, and is in insulated contact with the first line segment and the second line segment. All the common lines together form a pattern of a mesh.

Specifically, a first metal film layer is formed on the substrate, using a physical vapor deposition apparatus. The metal film layer is used for forming the patterning of a first layer comprising the gates, gate lines, and the common lines.

In step 710, the metal film layer is deposited on the substrate through a sputter coating method. The metal film layer is preferably made of any material selected from a group consisting of tantalum, molybdenum, chromium, Ti/Al/Ti laminated composite material, molybdenum-tantalum, aluminum molybdenum, and molybdenum-tungsten. In addition, dependent on different products, the thickness of the metal film can be in a range of 500 Å˜6000 Å.

And then, a photoresist is coated on the first metal film layer, and the patterning on a mask is transferred onto the photoresist through an exposure apparatus.

It is important to note that in the patterning on the mask, the gate line is formed as comprising a first line segment 11a and a second line segment 11b that are interrupted from each other, and the common line can pass through the interrupted region in a direction perpendicular to the gate line. All the common lines together form a pattern of a mesh.

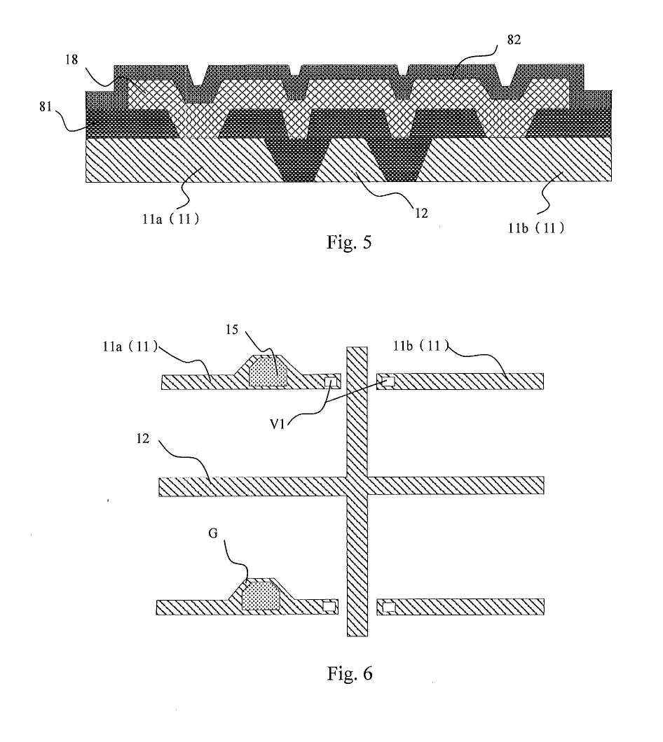

Finally, the part on the metal film layer which has not been covered with photoresist is etched off using a wet etching method, and then the photoresist is removed, thereby forming the patterning of the first layer. The metallic layer obtained is shown by reference signs 11 and 12 in FIG. 5, in which reference sign 12 indicates the common line, 11a indicates the first line segment, and 11b indicates the second line segment.

In step 720, a first insulation layer is formed on the gates, gate lines, and the common lines. Via holes are formed in the first insulation layer. Preferably, the via holes correspond to the respective ends of the first line segment and the second line segment that are adjacent to each other.

As shown in FIG. 5, a first insulation layer 81 overlays the common line 12 and gate line 11, and part of the first insulation layer 81 is embedded in a gap between the common line and the first line segment 11a and that between the common line 12 and the second line segment 11b.

In step 730, a data line, a source, a drain, and an electric connecting line are formed on the first insulation layer. The electric connecting line electrically connects the first line segment and the second line segment through the via holes formed in the first insulation layer.

As shown in FIG. 5, part of the electric connecting line 18 is embedded in the two via holes in the first insulation layer 81, and is in contact with the first line segment 11a and the second line segment 11b. The electric connecting line 18 is made of metallic material, such that the first line segment 11a and the second line segment 11b can be electrically connected.

Preferably, the electric connecting line 18 is made of any one selected from a group consisting of Ta, Mo, Cr, Ti/Al/Ti, Al/Mo, Mo/Ta, and Mo/W.

The technology of step 730 is substantially the same as that of step 710, thus will not be described in detail herein.

In step 740, a second insulation layer is formed on the data line, source, drain, and the electric connecting line. Via holes are formed in the second insulation layer. A pixel electrode is formed on the second insulation layer, and is electrically connected to the drain through the via holes formed in the second insulation layer.

In conclusion, according to the present disclosure, each of the gate lines of the array substrate is configured to be interrupted therein, so that the common lines each can pass through the interrupted region formed by the gate line to be short-circuited with one another in the effective display area, and at the same time the interrupted gate line segments are electrically connected with each other by providing a metallic layer. In this manner, the conductivity of the gate line would not be affected, and the uniformity of the optimum common voltage can be improved by short-circuiting the common lines together, thereby improving the product quality.

The above description should not be construed as limitations of the present disclosure, but merely as exemplifications of preferred embodiments thereof. Any variations or replacements that can be readily envisioned by those skilled in the art are intended to be within the scope of the present disclosure. The scope of the present disclosure should be subjected to that of the claims.

1. An array substrate, comprising a plurality of pixel units each having a gate line and a common line, wherein the gate line comprises a first line segment and a second line segment configured to be interrupted from each other,
an electric connection structure is disposed at an interrupted region between the first line segment and the second line segment, so that the first line segment and the second line segment are electrically connected with each other through the electric connection structure, and
the common line extends through said interrupted region in a direction perpendicular to the gate line, and is in insulated contact with the first line segment and the second line segment.

2. The array substrate according to claim 1, wherein the electric connection structure comprises via holes and an electric connecting line.

3. The array substrate according to claim 2, wherein the via holes respectively correspond to ends of the first line segment and the second line segment that are adjacent to each other,
the electric connecting line electrically connects the first line segment with the second line segment through the via holes, and
the electric connecting line is made of any one selected from a group consisting of Ta, Mo, Cr, Ti/Al/Ti, Al/Mo, Mo/Ta, and Mo/W.

4. A display panel comprising an array substrate, wherein the array substrate comprises a plurality of pixel units each having a gate line and a common line,
wherein the gate line comprises a first line segment and a second line segment configured to be interrupted from each other,
an electric connection structure is disposed at an interrupted region between the first line segment and the second line segment, so that the first line segment and the second line segment are electrically connected with each other through the electric connection structure, and
the common line extends through said interrupted region in a direction perpendicular to the gate line, and is in insulated contact with the first line segment and the second line segment.

5. The display panel according to claim 4, wherein the electric connection structure comprises via holes and an electric connecting line.

6. The display panel according to claim 5, wherein the via holes respectively correspond to ends of the first line segment and the second line segment that are adjacent to each other,
the electric connecting line electrically connects the first line segment with the second line segment through the via holes, and
the electric connecting line is made of any one selected from a group consisting of Ta, Mo, Cr, Ti/Al/Ti, Al/Mo, Mo/Ta, and Mo/W.

7. A method for manufacturing an array substrate, comprising:
forming a gate electrode, a gate line, and a common line on a substrate, wherein the gate line comprises a first line segment and a second line segment configured to be interrupted from each other, and the common line extends through an interrupted region in a direction perpendicular to the gate line, and is in insulated contact with the first line segment and the second line segment,
forming a first insulation layer on the gate, gate line and the common line, and forming in the first insulation layer via holes, which respectively correspond to the ends of the first line segment and the second line segment that are adjacent to each other,
forming a data line, a source, a drain, and an electric connecting line on the first insulation layer, the electric connecting line electrically connecting the first line segment with the second line segment through the via holes formed in the first insulation layer, and
forming a second insulation layer on the data line, source, drain, and the electric connecting line, forming a via hole in the second insulation layer and a pixel electrode on the second insulation layer, the drain being electrically connected with the pixel electrode through the via hole formed in the second insulation layer.

8. The method according to claim 7, wherein the electric connecting line is made of any one selected from a group consisting of Ta, Mo, Cr, Ti/Al/Ti, Al/Mo, Mo/Ta, and Mo/W.
